(19) United States
(12) Patent Application Publication
(10) Pub. No.: US 2025/0006466 A1
(43) Pub. Date: Jan. 2, 2025

(54) GAS FLOW DIFFUSORS FOR REMOTE PLASMA SOURCES

(71) Applicant: Advanced Energy Industries, Inc., Denver, CO (US)

(72) Inventors: Scott Polak, Fort Collins, CO (US); Joseph Porter, Fort Collins, CO (US); Ronald L. Pierce, Fort Collins, CO (US); Christian Conrady, Fort Collins, CO (US); Jordan Vin Raviv, Wellington, CO (US)

(21) Appl. No.: 18/345,665

(22) Filed: Jun. 30, 2023

(51) Int. Cl. H01J 37/32

(52) U.S. Cl. CPC H01J 37/32357; H01J 37/32449; H01J 37/32834; H01J 37/32862

(57) ABSTRACT

A remote plasma source (RPS) may include a toroidal chamber shaped to promote diffusion, reduce fluid velocity, and prolong fluid residence time in the RPS. A toroidal chamber may include an inlet, an outlet, an input leg, an output leg, and two interstitial legs connecting the input and output legs. A reference plane may bisect the toroidal chamber, the inlet, the outlet, and the four legs, wherein the inlet is substantially perpendicular to the reference plane and thereby configured to direct a fluid into the toroidal chamber substantially perpendicularly to the reference plane. A second inlet may be arranged in an opposing direction to the first inlet, either at the same corner of the input leg or at an opposing corner of the input leg.

### FIELD OF THE DISCLOSURE

The present disclosure relates generally to remote plasma sources. In particular, but not by way of limitation, the present disclosure relates to systems, methods and apparatuses for enhanced diffusion of gas flows into a remote plasma source.

### DESCRIPTION OF RELATED ART

Remote plasma sources (RPS) are used to modify a feed gas and deliver a stream of active, energetic, unstable gas species which are beneficial for the hardware or process occurring downstream of the RPS. These active gas species, such as atomic radicals, are used for numerous industrial and scientific applications including, but not limited to, processing solid materials and/or thin films such as those found on semiconductor wafers, display panels, and other active device substrates. Also, atomic radicals such as fluorine, chlorine, and oxygen are used to remove deposited thin films from semiconductor wafers or process chamber walls. RPS plasmas are also used to ionize and modify the gaseous waste in a pump stream, along with a reactant gas, and the resulting, compound products produced are either safer, less volatile, and/or easier to handle. In terms of on-wafer applications, etching, and deposition enhancement, and nitridation, are just a few additional applications of how an RPS adds benefit.

While some RPS use a linear or cylindrical chamber, toroidal sources have been developed in which currents are induced in a toroidal plasma contained within a generally toroidal chamber. These toroidal sources often use a ferrite-based transformer arrangement to inductively couple fields produced by a primary set of windings, concentrate the fields in the ferrite core and then induce currents in the plasma which makes up the secondary loop of the transformer. For instance, in FIG. 1A, a toroidal RPS source 104 has a ferrite core 108 wrapped around two legs of the toroidal RPS source 104, and a winding 110 wrapped around at least a portion of both ferrite cores 108.

The archetypical RPS has a gas inlet which is typically either a single jet, orifice, or vacuum pipe opening, such as the inlet 105 in FIG. 1A. Inductive or capacitive coupling is used to sustain a plasma within the toroidal RPS source 104 and gas is passed through the gas inlet 105, through the plasma within the toroidal RPS source 104, and then passed into the process chamber 106 downstream, typically via a gas outlet 107 having a cylindrical shape as seen in U.S. Patent Publication No. 2005/0082001 and U.S. Pat. No. 10,224,186. These references teach that since the gas is introduced into the process chamber with a pipe or similar structure, the gas can collide with a pipe wall or the like before entering the process chamber, thereby losing activation energy. As a result, the most-reactive species of gas (e.g., free radicals such as atomic fluorine, F, or atomic oxygen, O) will readily recombine into less-reactive, more stable molecules (e.g. F₂ or O₂), and therefore an extremely low percentage of dissociated, ionized, and otherwise manipulated gas may reach its intended target (U.S. Patent Application No. 2005/0082001 suggests that the percentage could be as low as 10%). Accordingly, these references teach methods to achieve improved laminar flow.

### SUMMARY OF THE DISCLOSURE

Both for environmental and financial reasons, it is desirable for the RPS to optimize the efficiency of dissociating feed gases as well as providing the dissociated gas to the process chamber. Beyond those challenges noted above, the inventors observed that another key factor in this optimization is increasing residence time or the time that gas particles spend in the RPS's chamber where power is being applied. Residence time in a remote plasma source refers to the duration that particles or species spend within the plasma region before exiting or undergoing further reactions. The residence time depends on several factors, including the gas flow characteristics, the volume of the RPS chamber, the distance between the plasma generation and processing regions, and the transport properties of the plasma species. Lower gas flow rates and longer distances between RPS input and output tend to increase residence time. The geometry of the plasma source, such as the shape and dimensions of the plasma chamber, can also influence the residence time.

It is important to control the residence time in a remote plasma source to achieve the desired processing effects. Longer residence times can allow for more extensive interactions between the plasma species and incident gases, leading to increased dissociation. However, designing for excessively long residence times can also result in unwanted side effects, such as reduced power density as a consequence of increasing chamber volume.

In addition to increasing residence time, the inventors focused on the distribution of velocities contributing to residence time. They discovered that there can be modes of operation where a small portion of the gas exhibits a long residence time while the bulk of the gas remains in a small, constrained stream. This results in a wide operating window but low destruction and removal efficiency (DRE). In order to achieve high DRE in conjunction with high power efficiency the inventors sought to narrow the velocity distribution of the gases as well as increase the residence time. Accordingly, the prior art was little help in solving these issues since it teaches methods to enhance laminar flow and thereby reduce residence time.

The inventors initially sought to increase residence time by reducing gas velocity in the RPS, first by increasing cross sectional areas of the chamber volumes perpendicular to the gas flow. For instance, given a tubular RPS with gas flowing along the length of the tubular volume, they increased RPS radius. Traditional, incompressible, viscous fluid dynamics suggest that this would lead to lower fluid velocity as diffusive interactions within the fluid spread the mass over a larger area perpendicular to the stream. However, RPSs operate in a near vacuum at extremely low fluid density and pressure, and, in most cases, the fluid velocity is supersonic yet laminar, compressible, and dominated by advective forces; in other words, the Péclet number is >>1. Thus, simple, traditional fluid behaviors and assumptions do not apply. In particular, the inventors discovered that gas, delivered into the RPS chamber through a small diameter gas line (for example, a ¼″ tube with compression fittings), will remain in a narrow, high-velocity streamline as it flows through the larger-diameter RPS chamber, essentially undisturbed, regardless of the RPS vacuum chamber cross-sectional area. In other words, the diffusive mechanisms within the fluid due to friction (collisions between particles) are not occurring on a fast enough time scale relative to the advective (velocity and pressure driven) physics to cause a sufficient reduction in fluid momentum; thus, unless something is done to enhance diffusion, the fluid will stream unimpeded through the RPS chamber and the residence time is only affected by fluid path length.

Recognizing that the RPS exhibits fluid behavior that is far less influenced by viscous, intermolecular forces, they turned towards alternative and novel means to promote diffusion, reduce fluid velocity, and prolong the fluid residence time in the RPS chamber. This disclosure describes various methods and apparatuses, arranged between a mass flow controller and a process chamber, that effect diffusion of gas(es) form the RPS inlet despite the low density and pressure seen within the RPS. In one aspect, the inlet and outlet are placed at the corners of the chamber therein elongating the path the gases traverse (e.g., see FIG. 3). In another aspect, the diffusers arrange the RPS chamber inlet and outlet at opposing corners of a donut-shaped chamber to increase a path length and thus residence time of inlet gas(es) (e.g., see FIGS. 4 and 6). In another aspect, the diffusers direct two inlet gas streams toward each other to mix, diffuse, and reduce velocity of the inlet gases (e.g., see FIG. 8A). In another aspect, the diffuser comprises a showerhead shaped to generate radially extending jets of gases that impinge on multiple walls before diffusing through the RPS chamber more generally (e.g., see FIG. 10A). In another aspect, the diffusers direct inlet gas(es) toward an angled corner of the RPS chamber (see FIGS. 9A and 11A) forcing the gas(es) to traverse a semicircular or u-shaped path before exiting the RPS chamber-thereby breaking up, diffusing, and reducing the velocity of the inlet gas(es) for the purpose of increasing residence time while also using this extended path length to increase residence time. Any of the herein disclosed diffusion structures can be implement with a single inlet, yet can further improve mixing of gases when multiple inlets are used. And it should be noted, that although certain embodiments are shown with one or two inlets, those of skill in the art will be able to carry these designs to implementation with more than two inlets. With increased residence time of any of the above-noted aspects, more efficient RPS dissociation and more stable plasma is achieved than has been possible in the art.

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In some aspects, the techniques described herein relate to a remote plasma source including: a toroidal chamber; a first inlet; an outlet; a reference plane bisecting the toroidal chamber, and the outlet, wherein the first inlet is substantially perpendicular to the reference plane and thereby configured to direct a fluid into the toroidal chamber substantially perpendicularly to the reference plane; and a magnetic field generating assembly encircling at least a portion of the toroidal chamber and configured to maintain a plasma within the toroidal chamber.

In some aspects, the techniques described herein relate to a remote plasma source including: a toroidal chamber; a magnetic field generating assembly configured to maintain a plasma within the toroidal chamber; a showerhead type jet inlet arranged on a first outer side of the toroidal chamber and having a first fluid flow axis, configured to receive a fluid at a first velocity, the showerhead type jet inlet including: a first inlet portion with a closed bottom; a second inlet portion wider than the first inlet portion; a plurality of radial jets configured to redirect the fluid from the first fluid flow axis toward walls of the second inlet portion; the second inlet portion configured to direct the gas into the toroidal chamber; and an outlet arranged on a second outer side of the toroidal chamber, opposing the showerhead type jet inlet, and having a second fluid flow axis substantially parallel to the first fluid flow axis. the first fluid flow axis directed toward an interior wall directly opposite the inlet.

In some aspects, the techniques described herein relate to a method for cleaning a process chamber including: introducing gas to a toroidal chamber of a remote plasma source in a first direction, the toroidal chamber having an input leg, a first interstitial leg, a second interstitial leg, and an output leg, wherein the first direction is perpendicular to a reference plane bisecting the input leg, the first interstitial leg, the second interstitial leg, and the output leg; generating a magnetic field encircling at least a portion of the toroidal chamber; maintaining a plasma within the toroidal chamber via the magnetic field configured to convert the gas to an activate gas; providing the activated gas to the process chamber and reacting the activated gas with a deposit inside the process chamber to at least partially remove the deposit; and exhausting the reacted gas from the process chamber.

In some aspects, the techniques described herein relate to a method of generating a plasma effluent from a remote plasma source, the effluent being usable for a variety of process chamber tasks such as cleaning and deposition enhancement, to name two non-limiting examples. The method can include introducing gas to a toroidal chamber of a remote plasma source in a first direction, the toroidal chamber having input leg, a first interstitial leg, a second interstitial leg, and an output leg, wherein the first direction is perpendicular to a reference plane bisecting the input leg, the first interstitial leg, the second interstitial leg, and the output leg. The method can further include generating a magnetic field encircling at least a portion of the toroidal chamber. The method can yet further include maintaining a plasma within the toroidal chamber via the magnetic field configured to convert the gas to an activate gas. The method can yet further include providing the activated gas to the process chamber. The method can also include exhausting the gas from the process chamber, for instance exhausting a reacted gas from the process chamber.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1A illustrates a cross section of a known RPS chamber with a toroidal shape and an inlet and outlet sharing a common axis.

FIG. 1B illustrates simulated fluid flow paths for the RPS chamber of FIG. 1A.

FIG. 2A illustrates a cross section of another known RPS chamber with an inlet at substantially a right angle to the outlet and in two opposing corners of a toroidal RPS chamber.

FIG. 2B illustrates simulated fluid flow paths for the RPS chamber of FIG. 2A.

FIG. 3 illustrates a known RPS chamber with an inlet arranged in a corner or end of an input leg of the RPS chamber.

FIG. 4A illustrates an embodiment of a toroidal chamber for an RPS with two inlets arranged in opposing corners of an input leg of the toroidal chamber and directed perpendicular to a reference plane that bisects the input leg, first and second interstitial legs, and an output leg.

FIG. 4B illustrates simulated fluid flow paths for the RPS chamber of FIG. 4A.

FIG. 5 illustrates an embodiment of a toroidal chamber for an RPS with an inlet arranged in a corner of an input leg of the toroidal chamber and directed perpendicular to a reference plane that bisects the input leg, first and second interstitial legs, and an output leg.

FIG. 6A illustrates an embodiment of a toroidal chamber for an RPS with two inlets arranged in opposing corners of an input leg of the toroidal chamber and directed perpendicular to a reference plane that bisects the input leg, first and second interstitial legs, and an output leg.

FIG. 6B illustrates simulated fluid flow paths for the RPS chamber of FIG. 6A.

FIG. 7 illustrates an embodiment of a toroidal chamber for an RPS with an inlet arranged in a corner of an input leg of the toroidal chamber and directed perpendicular to a reference plane that bisects the input leg, first and second interstitial legs, and an output leg.

FIG. 8A illustrates an embodiment of a toroidal chamber for an RPS with two inlets arranged in the same corner of an input leg of the toroidal chamber and directed perpendicular to a reference plane that bisects the input leg, first and second interstitial legs, and an output leg.

FIG. 8B illustrates simulated fluid flow paths for the RPS chamber of FIG. 8A.

FIG. 9A illustrates an embodiment of a toroidal chamber for an RPS with an inlet arranged opposite to a wedge-shaped protrusion.

FIG. 9B illustrates simulated fluid flow paths for the RPS chamber of FIG. 9A.

FIG. 9C provides an overhead cross-sectional view of the RPS chamber of FIG. 9A more clearly showing the shape of the wedge-shaped protrusion.

FIG. 10A illustrates an embodiment of an RPS chamber with a showerhead type jet diffuser arranged at its inlet.

FIG. 10B illustrates simulated fluid flow paths for the RPS chamber of FIG. 10A.

FIG. 10C provides a detailed view of the inlet of FIG. 10A.

FIG. 11A illustrates an embodiment of an inlet arranged on the same leg as the outlet and with an angled corner breaking up the input stream.

FIG. 11B illustrates simulated fluid flow paths for the RPS chamber of FIG. 11A.

FIG. 12 illustrates an overhead view of an RPS chamber with two angled inlets at the input leg.

FIG. 13 illustrates an overhead view of an RPS chamber with two inlets arranged parallel to a longitudinal axis of the input leg and coupled to the input leg.

FIG. 14 is a flowchart of an example method for providing a plasma effluent to a process chamber (e.g., for cleaning a process chamber).

FIG. 15 illustrates measured data for the efficiency of different diffuser topologies relative to dissociation of NF3.

### DETAILED DESCRIPTION

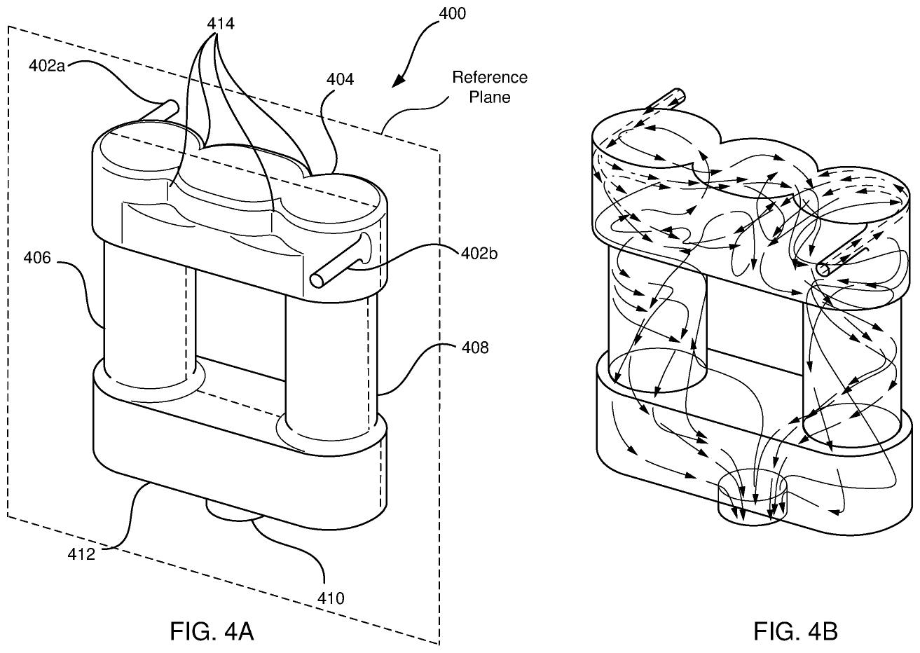

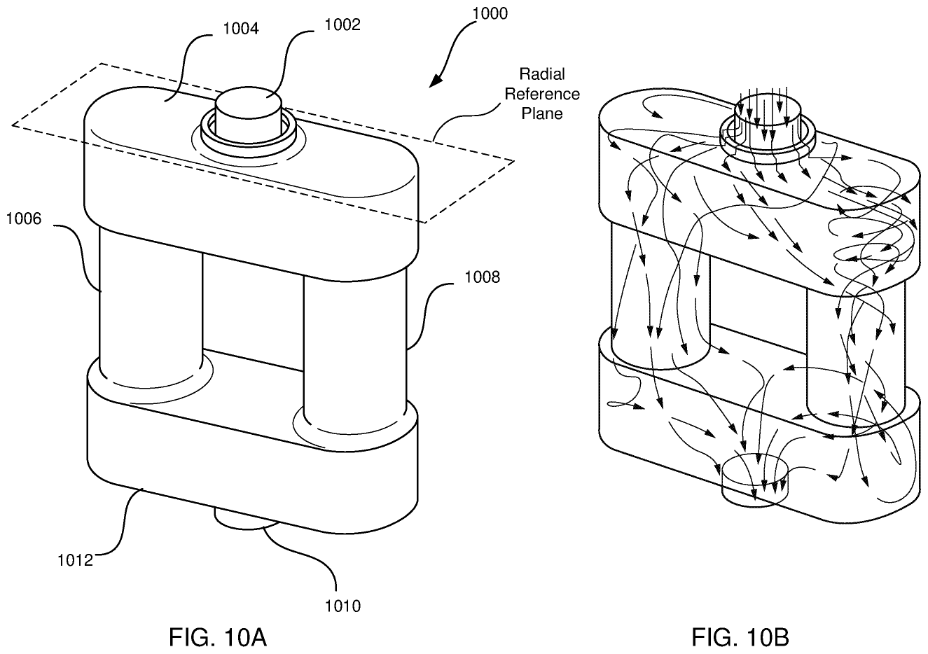

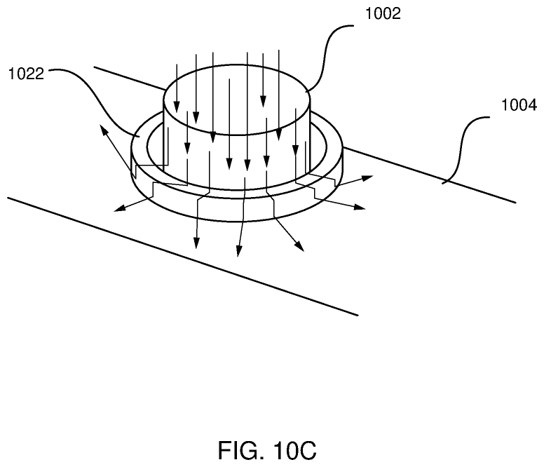

Prior to describing the embodiments in detail, it is expedient to define terms as used in this document. For the purpose of this document, relational terms such as, without limitation, “lateral”, “longitudinal”, “perpendicular”, “parallel”, and “flat” shall be understood to mean “within reasonable manufacturing tolerances accepted in the plasma processing manufacturing industry”. The term “longitudinal” shall reference that direction associated with a typical direction of travel or intended travel of a gas or a longest dimension of a component or structure. For example, in FIG. 4B, the gas generally travels parallel to a longitudinal axis of either of the second and third legs. The term “lateral” may reference any direction that is not longitudinal. For example, the reference plane in FIG. 10A is a lateral reference plane. The term “interior” shall reference surfaces and volumes within the remote plasma source chamber. For example, FIG. 10A shows an interior volume of a remote plasma process chamber with much of the remote plasma source itself hidden from view to make the chamber more easily seen. The term “nonlinear” shall be understood to mean having a curved region. For example, the perturbance fins toward the top of the input leg in FIG. 4A may be considered to form a nonlinear cross section for the input leg when viewed from above.

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the functionality and operation of possible implementations of a selector lever according to various embodiments of the present disclosure. It should be noted that, in some alternative implementations, the functions noted in each block may occur out of the order noted in the figures. For example, two blocks shown in succession may, in fact, be executed substantially concurrently, or the blocks may sometimes be executed in the reverse order, depending upon the functionality involved.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The diffuser may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups but do not preclude the presence or addition of one or more other features, integers, steps, operations, elements, components, and/or groups thereof. As used herein, the term “and/or” includes any and all combinations of one or more of the associated listed items, and may be abbreviated as “/”.

It will be understood that when an element or layer is referred to as being “on,” “connected to,” “coupled to,” or “adjacent to” another element or layer, it can be directly on, connected, coupled, or adjacent to the other element or layer, or intervening elements or layers may be present. In contrast, when an element is referred to as being “directly on,” “directly connected to,” “directly coupled to,” or “immediately adjacent to” another element or layer, there are no intervening elements or layers present. Likewise, when gas is received or provided “from” one element, it can be received or provided directly from that element or from an intervening element. On the other hand, when gas is received or provided “directly from” one element, there are no intervening elements present.

Embodiments of the disclosure are described herein with reference to cross-section illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Despite the art teaching away from remote plasma source configurations that break up streamlined fluid flow, the inventors recognized that the residence time of gas particles in a plasma chamber has a considerable influence on the characteristics of the plasma and the performance of the system. Due to high flow rates of gas and low (vacuum) pressure, the gas can move through a remote plasma chamber at supersonic speeds, with typical residence times as short as τ_{R}=10⁻⁴−10⁻³[s]. When the cycle rate of neutral gas approaches or exceeds the order of magnitude of the electron-neutral collision frequency,

$$\frac{{n}_{0}}{{τ}_{R}} > {v}_{ne} ,$$

there is insufficient time to fully dissociate (and/or ionize) the feedgas. Remote plasma sources (RPS) tend to have higher gas flow rates and smaller volumes (because of power density requirements and space limitations), compared to the downstream process chambers (not shown in FIGS. 4A-11, but in practice coupled to the output), which results in shorter residence times for the gases in an RPS. Next-generation RPS devices are pursuing unprecedented requirements for power efficiency and performance, as well as higher gas flow rates, which makes residence time optimization and manipulation critically important.

Thus, the inventors recognized a need to increase residence time in the RPS. However, it is difficult to estimate the residence time of gas in an RPS chamber because: (1) RPS chambers often feature complex, 3-dimensional topologies; (2) fluid behavior in RPS chambers is laminar, with little mixing or shear stresses to disturb streamlines; (3) energy is added to the fluid as it flows through the chamber, via collisions with energetic species in the plasma, which increases the internal energy or temperature of the gas and affects residence time; and (4) computational fluid dynamics software can predict the fluid flow through an RPS chamber, but does not account for the interaction with plasma, nor does the software provide a method for understanding the distribution of fluid residence times for individual fluid parcels or streamlines.

The inventors appreciated that existing CFD software solves the fluid conservation equations for conservation of mass, momentum, and energy, but not residence time. They added a fourth transport equation with a conserved parameter for residence time, added an experimentally correlated, phenomenological source term to the fluid energy equation to account for collisions with other species in the plasma which add internal energy to the feed gas(es), and began solving all four equations simultaneously. This level of rigor provided unseen insights into RPS chamber design. For instance, they discovered that subtle changes in chamber design can have significant effects on gas residence time, which led to simulations of chamber designs both similar and distinct from ones known in the art, both seeing profound effects on residence time. In other words, this work led the inventors to try subtle alterations to chamber design that would not have been obvious to try by those of skill in the art.

Some embodiments disclosed herein provide a remote plasma source having a gas source that is fed to the chamber via one or more inlets or a showerhead type jet diffuser that impart a longer and more consistent residence time on the particles and promotes increased diffusion of ingress gas density and momentum as compared to currently available devices. In some embodiments, a showerhead type jet diffuser is provided, that distributes gas through discrete orifices or channels, to impart a more uniform pressure and/or density and/or velocity of particles making up the gas.

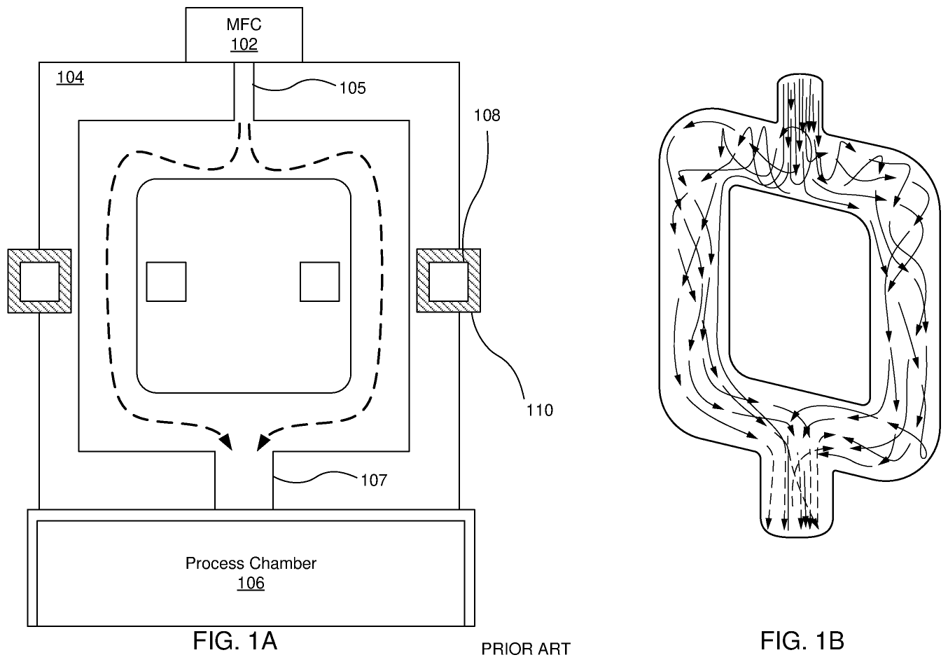

FIG. 1A illustrates a cross section of a known RPS chamber with a toroidal shape and an inlet and outlet sharing a common axis. FIG. 1A shows the RPS in cross section including arrows roughly following a path of gas through the toroidal chamber. Each leg of the toroidal chamber can be surrounded by a high-permeability ring, each with at least one conductive coil wrapping around the high-permeability ring. Passing a current through the coils causes magnetic flux to be induced in the high-permeability rings, which in turn induces a circular electric field within the toroidal volume and sustains a donut shaped plasma within the RPS. Within the donut-shaped plasma, gas(es) passing between the inlet and outlet are dissociated, ionized, and otherwise manipulated through collisions with energetic species in the plasma. The gas(es) passing through the inlet are controlled by a mass flow controller 102 and the outlet is coupled to and provides dissociated gas(es) to a process chamber 106.

As seen in the simulation of FIG. 1B, the inlet provides medium velocity gas into a wall of the input leg of the RPS, where the gas impinges upon the wall, creating a region of low temperature and high static pressure within the most active region of the plasma; the gas then scatters in both directions of the input leg towards either of the interstitial legs. This reduces the gas speed and increases diffusion of the gas. Diffuse flow somewhat continues as the gas spirals down the two interstitial legs at roughly equal rates. Another pair of 900 turns sends the gas toward the outlet, where the gas from each interstitial leg combines, rapidly accelerates, and is removed from the RPS at high speed. Although the RPS of FIG. 1A, successfully breaks up streamlined fluid flow from the inlet, overall residence time in the RPS is shorter-than-desired because: the incoming fluid cannot be guaranteed to be diffused and fully developed (i.e. when a boundary layer has formed along the walls and the velocity profile of the fluid is unchanging with increased distance along the fluid path), the gas follows the shortest possible path through the chamber (roughly one half of the total toroidal centerline path length), and the region of cold, high-static-pressure created from wall impingement is immediately within the most active region of plasma which is a toroidal shaped glow discharge hugging the inside walls of the RPS chamber

Those skilled in the art will readily recognize that not all elements of a plasma processing system are illustrated in FIG. 1; for example, a cooling coil is not illustrated, and a gas or plasma output section 107 is simplified for ease of reference. For ease of reference, in the embodiment illustrated in FIG. 1, it should be understood that fluid moves generally from an upstream region at the top of the figure towards a process chamber at the bottom of the figure.

FIG. 1B illustrates simulated fluid flow paths for the RPS chamber of FIG. 1A.

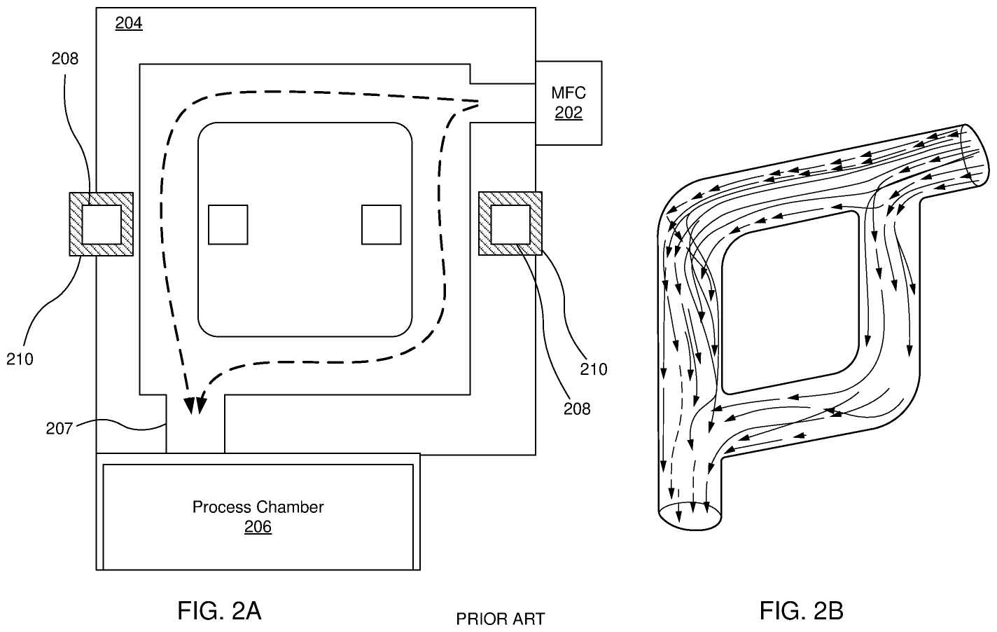

The inventors theorized that using larger inlets and outlets would reduce gas velocity. Yet, since the gas is passing through a vacuum, typical diffusion effects are greatly reduced, and in this case so reduced as to have little effect on streamline flow even with increased inlet and outlet cross sections. The RPS of FIG. 2 was a byproduct of unsuccessful attempts to reduce gas velocity by increasing the cross section through which the gas was passing. Furthermore, as mentioned previously, the design of FIG. 2 does not guarantee that the incoming gas flow is diffuse and fully developed. The user of the RPS may connect a small-diameter gas line to the gas inlet flange; as a result, the fluid flow through the chamber would be different, less diffuse, than shown in FIG. 2A, and the residence time would be significantly shorter.

FIG. 2A illustrates a cross section of another known RPS chamber with an inlet at substantially a right angle to the outlet and in two opposing corners of a toroidal RPS chamber. FIG. 2B illustrates simulated fluid flow paths for the RPS chamber of FIG. 2A. Each leg of the toroidal RPS source 204 can include a high-magnetic-permeability ring 208 (e.g., a ferromagnetic material), each with at least one conductive coil 210. Passing a current through the conductive coils 210 causes magnetic flux to be induced in the high-magnetic-permeability rings 208, which in turn induces a circular electric field within the toroidal volume and sustains a donut shaped plasma within the RPS. Within the donut-shaped plasma, gas(es) passing between the inlet and outlet are dissociated, ionized, and otherwise manipulated through collisions with energetic species in the plasma. The gas(es) passing through the inlet are controlled by a mass flow controller 202 and the outlet is coupled to and provides dissociated gas(es) to a process chamber 206.

As seen in the simulation of FIG. 2B, this RPS sees strong streamline flow of gases from the inlet along a first portion of the RPS in line with the inlet, while a smaller volume of gas turns and heads down a first of two legs of the RPS. At the end of both of these first two sections of gaseous passage, the gas hits a wall and takes a 90° turn, this turn causing some disturbance of streamlined flow and some reduced transit time. Finally, both gas paths intersect, the two streams coming together accelerate and are exhausted out the outlet at a higher-than-average velocity (see dashed lines). Although the RPS of FIG. 2A generates some mixing and disturbance to the fluid paths where gases have to make 90° turns, much of the streamlined flow and thus high inlet velocity is maintained throughout the RPS, which leads to shorter-than-desired residence times.

One can see by the density of the lines that a larger portion of gases pass through the input leg and the left interstitial leg than through the right interstitial leg and the output leg. This uneven distribution of gas can lead to uneven heating within the RPS as well as unevenly distributed residence times, which can hamper consistent gas dissociation in the RPS.

Those skilled in the art will readily recognize that not all elements of the plasma processing system are illustrated in FIG. 2A; for example, a cooling coil is not illustrated, and a gas or plasma output section 207 is simplified for ease of reference. For ease of reference, in the embodiment illustrated in FIG. 2A, it should be understood that fluid moves generally from an upstream region at the top of the figure towards a process chamber at the bottom of the figure.

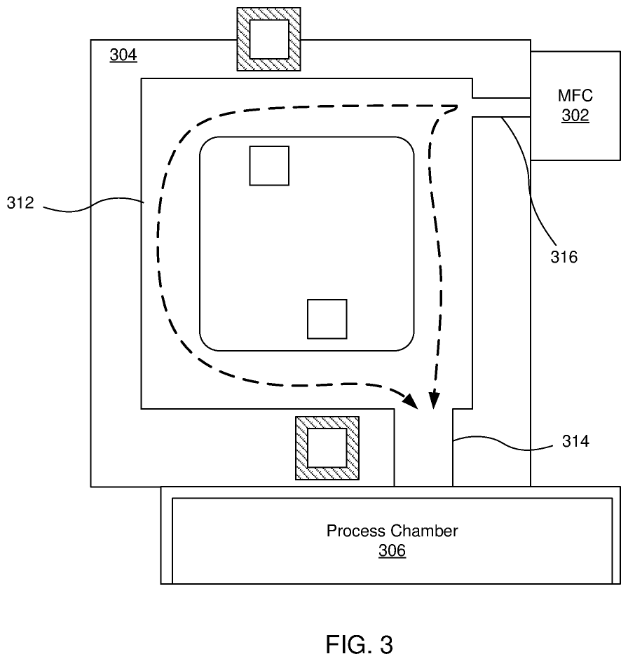

FIG. 3 illustrates a known vacuum space formed by inner walls of an RPS chamber with an inlet arranged in a corner or end of an input leg of the RPS chamber. Similar to the design seen in FIGS. 2A and 2B, a mass flow controller (MFC) 302 regulates the flow of gas into the vacuum space 312 of the toroidal RPS source 304 through an input 316 and an output 314 carries activated gas to a process chamber 306. The output 314 is arranged off of an output leg and more specifically off of a corner of the output leg on the same side of the vacuum space 312 as the input 316. Given this proximity of the input 316 and the output 314, the gas takes two distinct routes having different path lengths. As a result, different gas particles see vastly different residence times, which leads to inconsistent activation processes and thus degraded performance in process chamber 306.

FIGS. 4 through 11 show various innovative vacuum spaces of inner walls of RPS chambers designed to achieve longer and more consistent residence time through an entire distribution of gas particles passing through an RPS.

FIG. 4A illustrates an embodiment of a toroidal chamber 400 for an RPS with two inlets 402a and 402b arranged in opposing corners of an input leg 404 of the toroidal chamber 400 and directed perpendicular to a reference plane that bisects the input leg 404, first and second interstitial legs 406 and 408, and an output leg 412. The toroidal chamber 400 also includes perturbance fins 414 arranged within a top portion of the input leg 404. Conductors, magnets, and power supplies for maintaining a plasma within the toroidal chamber 400 are not shown, but will be easily-implemented by those of skill in the art, for instance, taking a form similar to 208 and 210 shown in FIG. 2B. These components can be arranged to form a magnetic field generating assembly (not shown) encircling at least a portion of the toroidal chamber 400 and can be configured to maintain a plasma within the toroidal chamber 400. For instance, the magnetic field generating assembly could encircle the input leg 404, the first or second interstitial legs 406/408, the output leg 412, or any combination of these. The first and second interstitial legs 406/408 are spaced apart and connecting ends of the input leg 404 and the output leg 412. The input leg 404 and the output leg 412 can have a generally racetrack-shaped volume.

As seen in the gas flow simulation of FIG. 4B, gas enters the input leg 404 of the toroidal chamber 400 at a higher velocity from both inlets 402a and 402b, but then rapidly decelerates upon impinging on an opposing wall of the input leg 404. Further, as the two gas streams decelerate and expand upon these interactions with the walls opposing the inlets 402a and 402b, the two gas streams begin to move toward each other and collide increasingly toward a center of the input leg 404, further decelerating the two gas streams and enhancing diffusion in input leg 404. Eventually, both gas streams migrate to two interstitial legs 406 and 408, and with equal mass flow and residence time, descend in a spiral fashion to an output leg 412 where both streams then move toward each other and are exhausted via the outlet 410 in the middle of the output leg 412. The input leg 404 has a racetrack shape with two curved ends, two long linear sides, and a cross section when viewed from above that is consistent throughout its height. However, to further reduce fluid velocity and break up streamline flow, an upper portion of the input leg 404 can include four perturbance fins 414 that breakup streamline flow of fluid around a periphery or perimeter of the input leg 404. Gases that impinge on these four perturbance fins 414 decelerate and spread and are pushed toward a center of the input leg 404 via these perturbance fins 414, and this disturbance further breaks up high velocity streamlines of the two gas streams circling the racetrack-shaped input leg 404. In the illustrated embodiment, the four perturbance fins 414 break up the upper portion of the input leg 404 into three circular or elliptical regions (when viewed from above), though in other embodiments, fewer than or more than four perturbance fins 414 could be implemented and more or fewer than three circular or elliptical regions could be formed. The four perturbance fins 414 are used on an upper portion of the input leg 404, but not on a lower portion since plasma density tends to predominate in the lower portion of the input leg 404 and the smoother lower portion is better tailored to plasma formation and maintenance. In this way, the input leg 404 can both break up high-velocity streamlines of incoming gases, improve diffusion, and increase residence time of the incoming streams, while still optimizing plasma density closer to a center of the toroidal chamber 400. In some cases, though not shown, a height of the input leg 404 could be greater than a height of the output leg 412 so that a volume of the input leg 404 where plasma density is highest is roughly similar in volume to that of the output leg 412.

A reference plane is shown that bisects the toroidal chamber 400 and the outlet 410 and where the first inlet 402a and the second inlet 402b are substantially perpendicular to the reference plane. In other words, the first and second inlets 402a and 402b are arranged in opposing directions (parallel to a common axis, though not aligned on that same axis). In this way, the inlets 402a and 402b are configured to direct a fluid into the toroidal chamber 400 substantially perpendicularly to the reference plane. By directing fluid into the input leg 404 at opposing ends of the input leg 404 and in opposing directions, the inventors found that input velocity is substantially reduced, mixing of the two streams is enhanced, and overall residence time of the fluid is enhanced and equally distributed between the two streams (or between two streams between the input leg 404 and the outlet 410). Said another way, symmetric positioning of the inlets 402a and 402b at opposing corners and on opposing sides of the input leg 404, enables two equal path lengths, and thus substantially equal residence time along the two equal path lengths, leading to substantially equal volumetric rates of gas transfer between the inlets 402a and 402b and the outlet 410. These effects are seen in the simulation of FIG. 4B where fluid velocity is greatest at the inlets 402a and 402b and the outlet 410 as shown by the shorter arrows, but is reduced while traveling between the inlets 402a/402b and the outlet 410 as shown by the longer arrows.

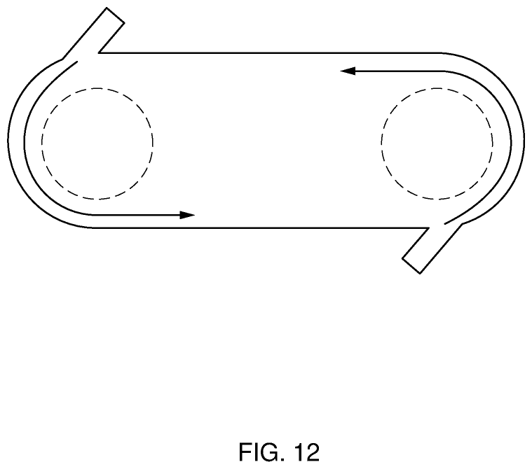

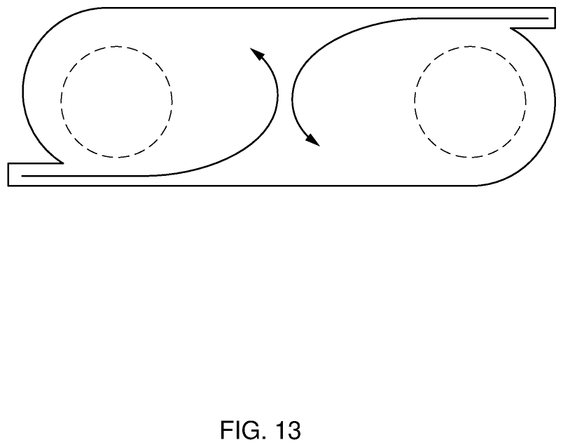

While the inlets 402a and 402b are shown as being aligned parallel to a common axis (or both perpendicular to a reference plane passing through all four legs of the toroidal chamber 400), the inlets 402a and 402b could also be arranged at some angle relative to the reference plane, such as shown in the overhead view of FIG. 12. Here the inlet angels are shown at around 45°, but in other embodiments, could use similar angles, such as, but not limited to, 30°, 40°, 50°, 60°. Alternatively, the inlets could be arranged at opposing corners of the input leg 404, yet both be angled parallel to a common axis, yet both offset from that axis as seen in FIG. 13.

It will be appreciated that various RPS can be implemented around the illustrated inner walls of the toroidal chamber 400, and therefore the shape and form of the RPS surrounding the toroidal chamber 400, or volume, is non-limiting.

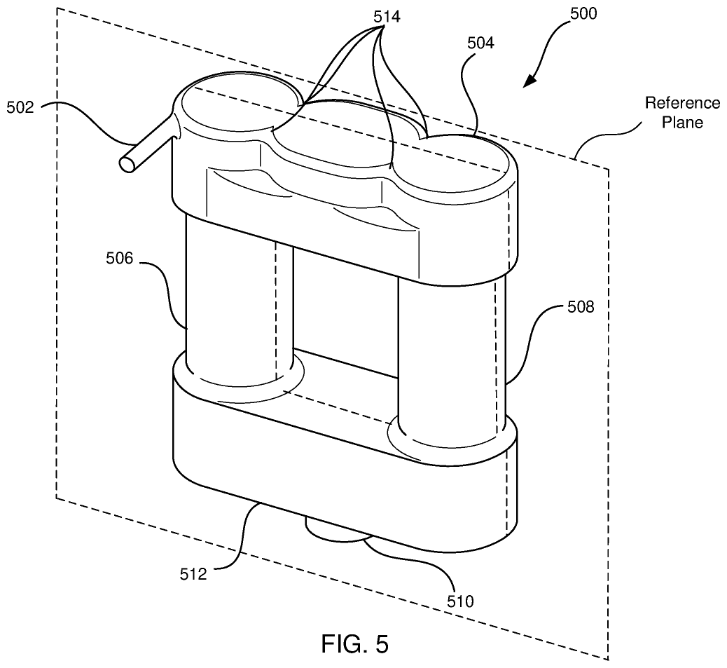

A single inlet at either of the positions shown in FIG. 4A can also provide substantial improvements over the art. FIG. 5 illustrates an embodiment of a toroidal chamber 500 for an RPS with an inlet 502 arranged in a corner of an input leg 504 of the toroidal chamber 500 and directed perpendicular to a reference plane that bisects the input leg 504, first and second interstitial legs 506 and 508, and an output leg 512. The toroidal chamber 500 also includes perturbance fins 514 arranged within a top portion of the input leg 504. Conductors, magnets, and power supplies for maintaining a plasma within the toroidal chamber 500 are not shown, but will be easily-implemented by those of skill in the art, for instance, taking a form similar to 208 and 210 shown in FIG. 2B. These components can be arranged to form a magnetic field generating assembly (not shown) encircling at least a portion of the toroidal chamber 500 and can be configured to maintain a plasma within the toroidal chamber 500. For instance, the magnetic field generating assembly could encircle the input leg 504, the first or second interstitial legs 506/508, the output leg 512, or any combination of these. The first and second interstitial legs 506/508 are spaced apart and connecting ends of the input leg 504 and the output leg 512. The input leg 504 has a racetrack shape with two curved ends, two long linear sides, and a cross section when viewed from above that is consistent throughout its height. However, to further reduce fluid velocity and break up streamlined flow, an upper portion of the input leg 504 can include four perturbance fins 514 that breakup streamline flow of fluid around a periphery or perimeter of the input leg 504. Gases that impinge on these four perturbance fins 514 decelerate and are pushed toward a center of the input leg 504 via these perturbance fins 514, and this disturbance further breaks up streamlined flow of the input fluid stream circulating through the racetrack-shaped input leg 504. In the illustrated embodiment, the four perturbance fins 514 break up the upper portion of the input leg 504 into three circular or elliptical regions (when viewed from above), though in other embodiments, fewer than or more than four perturbance fins 514 could be implemented and more or fewer than three circular or elliptical regions could be formed. The four perturbance fins 514 are used on an upper portion of the input leg 504, but not on a lower portion since plasma density tends to predominate in the lower portion of the input leg 504 and the smoother lower portion is better tailored to plasma formation and maintenance. In this way, the input leg 504 can both break up streamlined flow of incoming gases, improve diffusion, and increase residence time of the incoming streams, while still optimizing plasma density closer to a center of the toroidal chamber 500. In some cases, though not shown, a height of the input leg 504 could be greater than a height of the output leg 512 so that a volume of the input leg 504 where plasma density is highest is roughly similar in volume to that of the output leg 512.

A reference plane is shown that bisects the toroidal chamber 500 and the outlet 510 and where the inlet 502 is substantially perpendicular to the reference plane. By directing fluid into the input leg 504 at a corner and at an angle roughly perpendicular to the reference plane, the inventors found that input velocity is substantially reduced, mixing of the input stream on itself is increased, and overall residence time of the fluid is enhanced and more evenly distributed as fluid chooses which of the two interstitial legs 506 and 508 to follow en route to the outlet 510.

While the inlet 502 is shown as being perpendicular to the reference plane passing through all four legs of the toroidal chamber 500, the inlet 502 could also be arranged at some angle relative to the reference plane, such as, but not limited to, a 30°, 40°, 45°, 50°, and 60°. Alternatively, the inlet 502 could be arranged parallel to the reference plane but off-axis from the reference plane such that incoming fluid is incident on one of the four perturbance fins 514.

It should be noted that FIG. 5 may not achieve the same equal distribution of residence time since the path length between the two routes to outlet 510 are different and the paths have different chamber shapes.

It will be appreciated that various RPS can be implemented around the illustrated inner walls of the toroidal chamber 500, and therefore the shape and form of the RPS surrounding the toroidal chamber 500, or volume, is non-limiting.

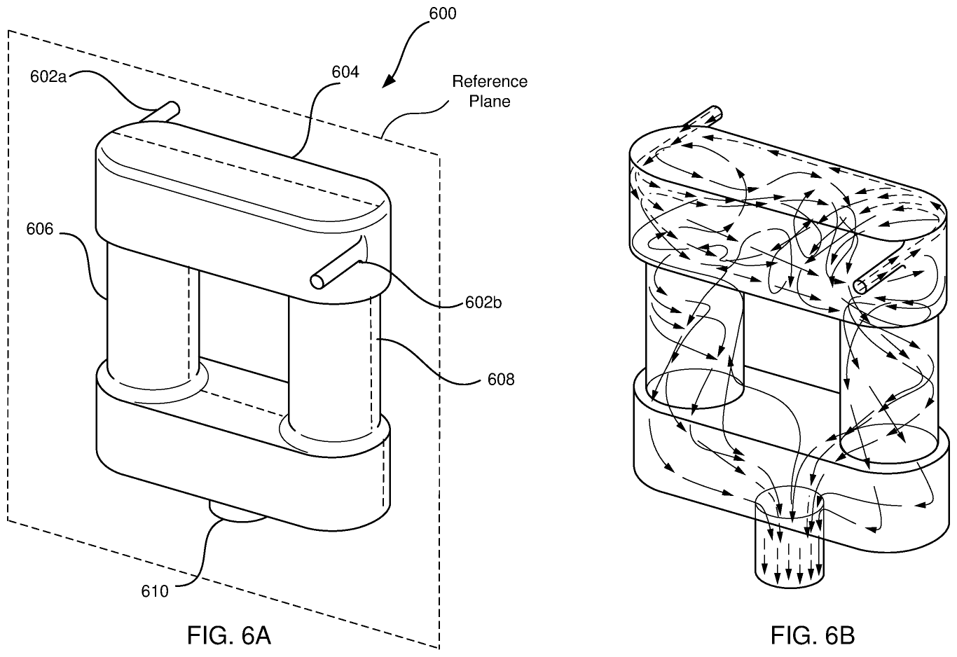

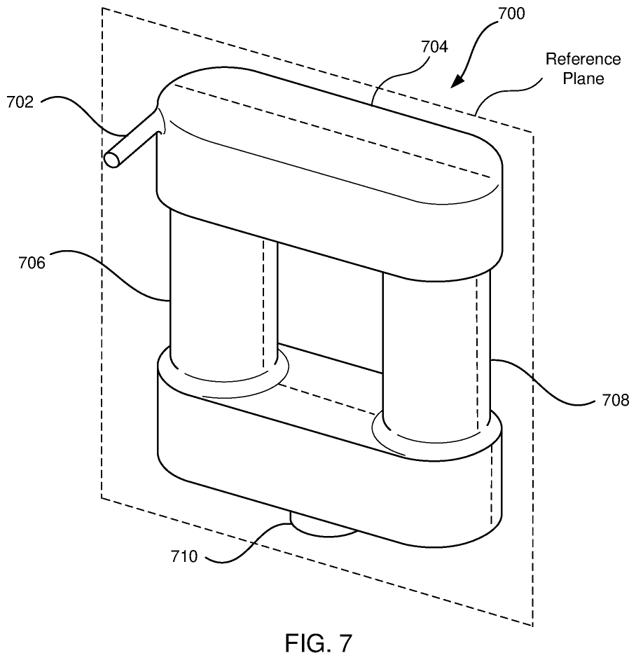

The toroidal chamber of FIG. 6A and the accompanying simulation in FIG. 6B, show that removal of the perturbance fins seen in FIGS. 4A and 5, while slightly less effective than those designs, still achieves significant breakup of streamline flow from the inlets 602a and 602b, as well as mixing of the two input streams, and enhanced residence time. Along these same lines, a single inlet can be implemented as shown in FIG. 7, with similar residence times to those seen in FIGS. 6A and 6B. As with FIG. 6A, inlet 702 is arranged perpendicular to a reference plane, and the input leg 704 has a smooth racetrack shape without perturbance fins. It should be noted that FIG. 7 may not achieve the same equal distribution of residence time seen in FIG. 6A since the path length between the two routes to outlet 710 are different and the paths have different chamber shapes.

In FIG. 6A, a reference plane is shown that bisects the toroidal chamber 600 and the outlet 610 and where the inlets 602a and 602b are substantially perpendicular to their respective reference planes. By directing fluid into the input leg 604 at corners and roughly perpendicular to the reference plane, the inventors found that input velocity is substantially reduced, mixing of the input stream on itself is increased, and overall residence time of the fluid is enhanced and more evenly distributed as fluid chooses which of the two interstitial legs 606 and 608 to follow en route to the outlet 610.

While the inlets 602a and 602b are shown as being perpendicular to the reference plane passing through all four legs of the toroidal chamber 600, the inlets 602a and 602b could also be arranged at some angle relative to the reference plane, such as, but not limited to, a 30°, 40°, 45°, 50°, and 60°. Alternatively, the inlets 602a and 602b could be arranged parallel to the reference plane but off-axis from the reference plane.

In FIG. 7, a reference plane is shown that bisects the toroidal chamber 700 and the outlet 710 and where the inlet 702 is substantially perpendicular to the reference plane. By directing fluid into the input leg 704 at a corner and roughly perpendicular to the reference plane, the inventors found that input velocity is substantially reduced, mixing of the input stream on itself is increased, and overall residence time of the fluid is enhanced and more evenly distributed as fluid chooses which of the two interstitial legs 706 and 708 to follow en route to the outlet 710.

While the inlet 702 is shown as being perpendicular to the reference plane passing through all four legs of the toroidal chamber 700, the inlet 702 could also be arranged at some angle relative to the reference plane, such as, but not limited to, a 30°, 40°, 45°, 50°, and 60°. Alternatively, the inlet 702 could be arranged parallel to the reference plane but off-axis from the reference plane.

It will be appreciated that various RPS can be implemented around the illustrated inner walls of the toroidal chambers 600 and 700, and therefore the shape and form of the RPS surrounding the toroidal chambers 600 and 700, or volumes, are non-limiting.

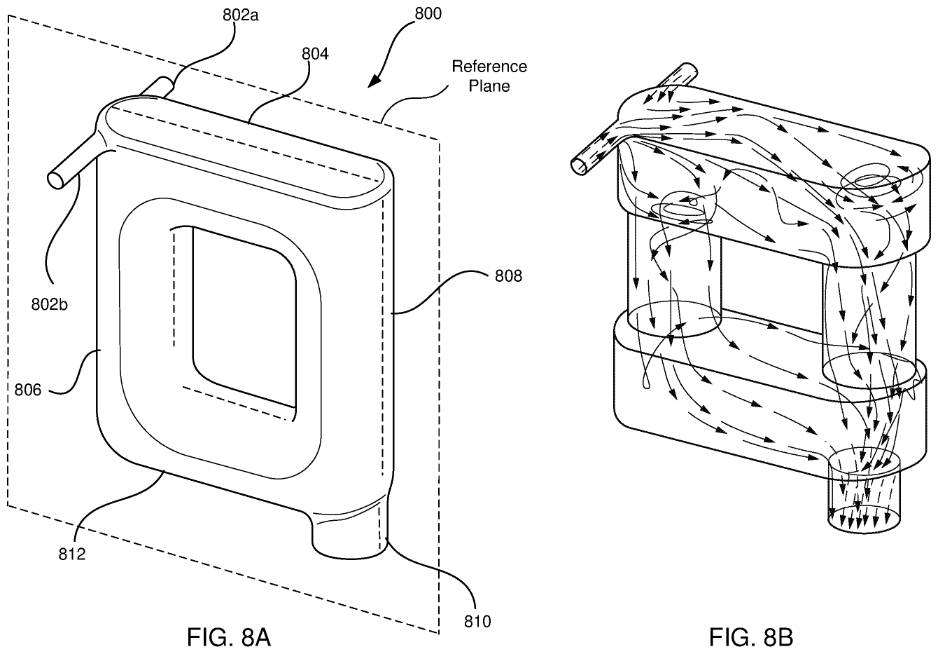

FIG. 8A illustrates an embodiment of a toroidal chamber 800 for an RPS with two inlets 802a and 802b arranged in the same corner of an input leg 804 of the toroidal chamber 800 and directed perpendicular to a reference plane that bisects the input leg 804, first and second interstitial legs 806 and 808, and an output leg 812. Conductors, magnets, and power supplies for maintaining plasma within the toroidal chamber 800 are not shown, but will be easily implemented by those of skill in the art, for instance, taking a form similar to 208 and 210 shown in FIG. 2B. These components can be arranged to form a magnetic field generating assembly (not shown) encircling at least a portion of the toroidal chamber 800 and can be configured to maintain a plasma within the toroidal chamber 800. For instance, the magnetic field generating assembly could encircle the input leg 804, the first or second interstitial legs 806/808, the output leg 812, or any combination of these. The first and second interstitial legs 806/808 are spaced apart and connecting ends of the input leg 804 and the output leg 812. As seen in the gas flow simulation of FIG. 8B, gas enters the input leg 804 of the toroidal chamber 800 at a higher velocity from both inlets 802a and 802b, but then rapidly decelerates as the two streams collide. The fluid path from this collision region to outlet 810 at an opposing corner of the output leg 812 means that substantially equal path lengths are seen whether the fluid passes through the first or second interstitial legs 806/808. Thus, residence time is both increased with this design as well as maintained substantially constant between all gas particles.

A reference plane is shown that bisects the toroidal chamber 800 and the outlet 810 and where the first inlet 802a and the second inlet 802b are substantially perpendicular to the reference plane. In other words, the first and second inlets 802a and 802b are arranged in opposing directions along a common axis. In this way, the inlets 802a and 802b are configured to direct a fluid into the toroidal chamber 800 substantially perpendicularly to the reference plane. By directing fluid into the input leg 804 at the same end of the input leg 804 and in opposing directions and with the outlet arranged at an opposing corner of the output leg 812, the inventors found that input velocity is substantially reduced, mixing of the two streams is enhanced, and overall residence time of the fluid is enhanced and equally distributed between the two streams. These effects are seen in the simulation of FIG. 8B where fluid velocity is greatest at the inlets 802a and 802b and the outlet 810 as shown by the shorter arrows, but is reduced while traveling between the inlets 802a/802b and the outlet 810 as shown by the longer arrows.

While the inlets 802a and 802b are shown as being aligned parallel to a common axis (or both perpendicular to a reference plane passing through all four legs of the toroidal chamber 800), the inlets 802a and 802b could also be arranged at some angle relative to the reference plane. These angles could include, but are not limited to, 30°, 40°, 45°, 50°, and 60°.

It will be appreciated that various RPS can be implemented around the illustrated inner walls of the toroidal chamber 800, and therefore the shape and form of the RPS surrounding the toroidal chamber 800, or volume, is non-limiting.

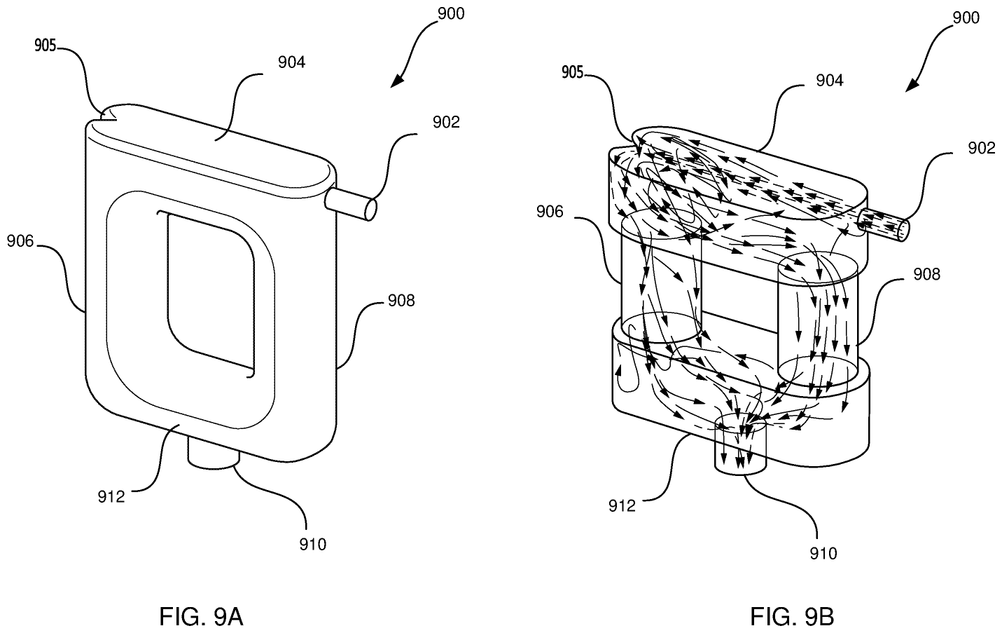

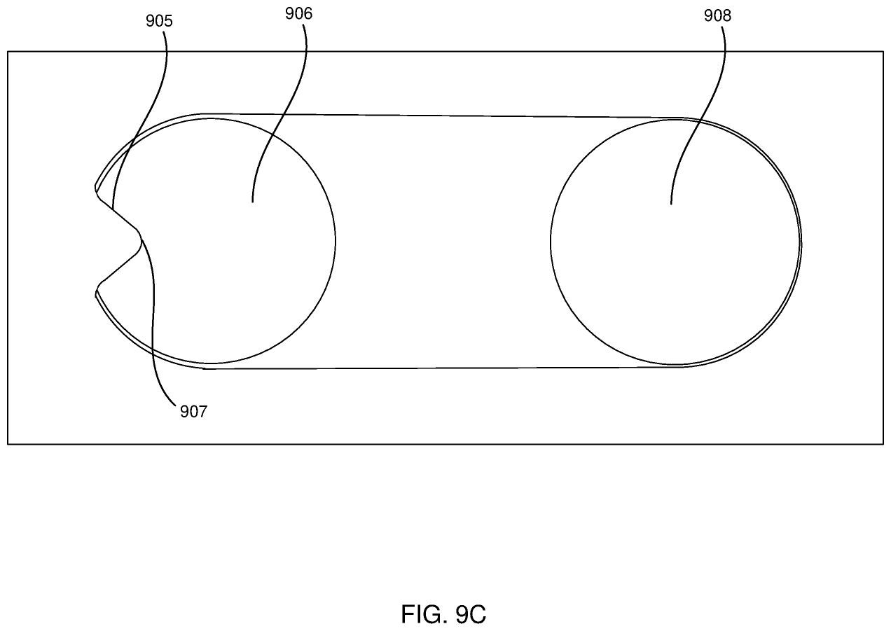

FIG. 9A illustrates an embodiment of a toroidal chamber 900 for an RPS with an inlet arranged opposite to a wedge-shaped protrusion. In particular, an inlet 902 is arranged at an end of an input leg 904 and is directed parallel to a long axis of the input leg 904 such that the incoming gas travels a length of the input leg 904 before impinging on a wall shaped to disturb streamlines of the gas, for instance, including a wedge-shaped protrusion 905. This shape encourages the gas to spread and rotate back toward inlet 902, some of the gas returning the length of the input leg 904, and some spinning down a first interstitial leg 906. The gas that passes back along the input leg 904 and toward the inlet 902 then curves and passes down a second interstitial leg 908. The outlet 910 can be arranged at a middle of an output leg 912 and the gases from the first and second interstitial legs 906, 908 exit through the outlet 910 at a higher velocity than they experienced after impinging on the wedge-shaped protrusion 905.

This design achieves extended residence times as shown in FIG. 9B, where simulated flow paths show a substantial reduction in velocity once the gas impinges on the wedge-shaped protrusion 905. From there, the gas can take a shorter path through the first interstitial leg 906, and along a portion of the output leg 912 before exiting through the outlet 910, while the gas can also take the longer path back through the input leg 904, through the second interstitial leg 908, and along at least a portion of the output leg 912. A traditional RPS having a similar shape would see most gas pass circle in a C-shape from the input to the output with insignificant decrease in the high input velocity and little to no disruption of streamlined flow. In contrast, inclusion of the wedge-shaped protrusion 905 slows the velocity of gas passing through the interstitial legs 906 and 908, and greatly increases a path length and thus residence time of gas that swings back along the input leg 904 since this gas basically backtracks a portion of its route through the toroidal chamber 900. Thus, even a small modification to the toroidal chamber 900, such as inclusion of the wedge-shaped protrusion 905 can lead to significant and desirable increases in residence time, increased radical flux, reduced power consumption, reduced pross time, and increased throughput.

Although the outlet 910 is shown in a middle of the output leg 912, in other embodiments, the output could be arranged at either end of the output leg 912. For instance, the input could be arranged at a first corner and the outlet could be arranged at a second corner separated from the input by a corner of the toroidal RPS chamber.

FIG. 9C provides an overhead cross-sectional view of the RPS chamber of FIG. 9A more clearly showing the shape of the wedge-shaped protrusion 905. However, the wedge-shaped protrusion 905 can be replaced by other shapes such as wedges having different angles and those having more or less of a curved nose 907. In some embodiments, the curved nose 907 can be replaced by a sharp or angled nose. Typically, the curved nose 907 will be aligned with the inlet 902 such that the gas is equally split on both sides of the curved nose 907 (i.e., ‘above’ and ‘below’ the curved nose 907 as viewed in FIG. 9C).

It will be appreciated that various RPS can be implemented around the illustrated inner walls of the toroidal chamber 900, and therefore the shape and form of the RPS surrounding the toroidal chamber 900, or volume, is non-limiting.

FIG. 10A illustrates an embodiment of an RPS chamber with a showerhead type jet diffuser arranged at its inlet. In particular, the showerhead type jet inlet 1002 is arranged at a top middle of an input leg 1004 while the outlet 1010 is arranged at a middle bottom of an output leg 1012 (i.e., an outer side of the toroidal chamber). The showerhead type jet inlet 1002 includes a series of radially extending tubes radiating outward from the showerhead type jet inlet 1002 in the illustrated radial reference plane. The showerhead type jet inlet 1002 includes a first portion and a second portion. The first portion has an open top, a closed bottom and a first radius. The second portion has a closed top, an open bottom, and a second radius greater than the first radius. Radial jets extend between the first and second portions such that fluid in the showerhead type jet inlet 1002 is forced to drastically change direction at a bottom of the first portion, jog sideways along the radial reference plane, and then impact a wall of the second portion before being diffused down into the input leg 1004. Details of the showerhead type jets are better seen in FIG. 10C. The first and second portions are both concentrically aligned with a fluid flow axis that also aligns with the outlet 1010. The fluid flow axis is also directed toward an interior wall of the toroidal chamber 1000 directly opposite the showerhead type jet inlet 1002. Said another way, the showerhead type jet inlet 1002 is arranged on a first outer side of the toroidal chamber 1000 and has a first fluid flow axis, and the outlet 1010 is arranged on a second outer side of the toroidal chamber 1000, opposing the showerhead type jet inlet 1002, and has a second fluid flow axis substantially parallel to the first fluid flow axis. The first and second fluid flow axes are coextensive as this ensures equal path lengths for gases choosing the first versus the second interstitial leg 1006 and 1008.

From the simulation in FIG. 10B one can see that these radiating jets actually increase gaseous velocity since they constrict the cross section of gas flow at the showerhead type jet inlet 1002. However, by redirecting the jets in the radial reference plane and directing them into walls of the wider portion 1022 of the showerhead type jet inlet 1002, the gas sees a dramatic reduction in velocity and a dramatic increase in diffusion and disturbance in streamlined flow upon impacting or approaching the sidewalls of the wider portion of the showerhead type jet inlet 1002. Said another way, the jets cause a lower velocity gas over a larger area, which greatly improves residence time and without hampering the stability of the plasma. The slower moving gas is then able to slowly diffuse through both paths of the toroidal chamber 1000 and out the outlet 1010.

It will be appreciated that various RPS can be implemented around the illustrated inner walls of the toroidal chamber 1000, and therefore the shape and form of the RPS surrounding the toroidal chamber 1000, or volume, is non-limiting.

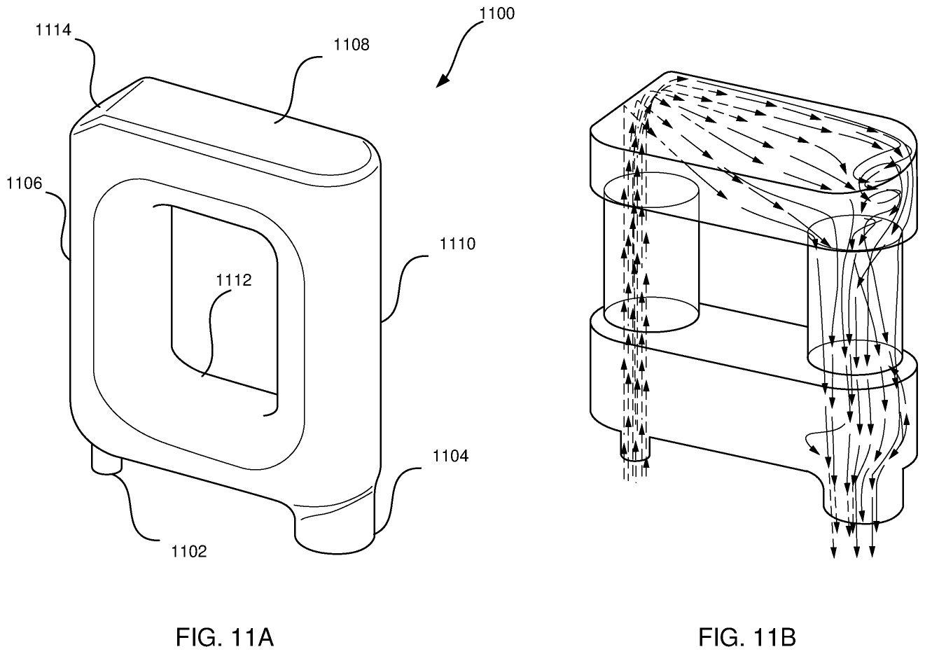

FIG. 11A illustrates an embodiment of an inlet arranged on a same leg as the outlet. In this embodiment, the toroidal chamber 1100 includes four legs, where the inlet 1102 is coupled to an input leg 1106 in a longitudinal direction relative to the input leg 1106, and the output 1104 is coupled to a fourth leg 1112 in a longitudinal direction relative to the third leg 1110. This configuration elongates the path length between the inlet 1102 and the output 1104, since the input stream passes the full length of the input leg 1106 and the second and third legs 1108 and 1110. Additionally, corner 1114, between the input leg 1106 and the second leg 1108, can have an angled face relative to the longitudinal axis of the input leg 1106 and the input stream. The input stream travels relatively undisturbed through the input leg 1106, but then impinges on the angled face of the corner 1114 causing expansion of the stream, deceleration, and diffusion of the gas, which then fills the second leg 1108 and moves more slowly toward the turn to the third leg 1110. In this variation, relative volumetric flow between inlet 1102 and the output 1104 via the fourth leg 1112 is low, and as such the gas particles largely see consistent residence time.

It will be appreciated that various RPS can be implemented around the illustrated inner walls of the toroidal chamber 1100, and therefore the shape and form of the RPS surrounding the toroidal chamber 1100, or volume, is non-limiting.

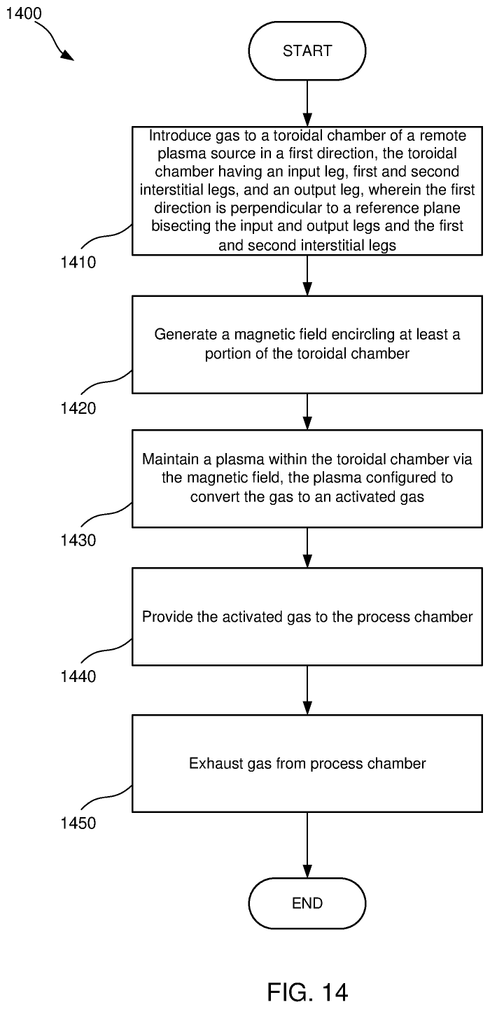

FIG. 14 is a flowchart of an example method for providing a remote plasma source effluent to a process chamber (e.g., for cleaning a process chamber). At step 1410, the method 1400 includes introducing gas to a toroidal chamber of a remote plasma source in a first direction, the toroidal chamber having input leg, a first interstitial leg, a second interstitial leg, and an output leg, wherein the first direction is perpendicular to a reference plane bisecting the input leg, the first interstitial leg, the second interstitial leg, and the output leg. At step 1420, method 1400 includes generating a magnetic field encircling at least a portion of the toroidal chamber. At step 1430, method 1400 includes maintaining plasma within the toroidal chamber via the magnetic field configured to convert the gas to an activate gas. At step 1440, the method includes providing the activated gas to the process chamber. For instance, the activated gas could be reacted with a deposit inside the process chamber to at least partially remove the deposit. At step 1450, method 1400 includes exhausting the gas from the process chamber, for instance exhausting a reacted gas from the process chamber.

In an alternative embodiment, a method for providing a plasma effluent to a process chamber is disclosed. The method can include: introducing gas to an inlet of a remote plasma source toroidal chamber, the inlet having two portions, a first with a narrower radius and showerhead type jets, and a second with a wider radius; redirecting the gas through the jets and impinging the gas on the wall of the second portion of the inlet; decelerating and diffusing the gas via the change in direction and impingement on the second portion of the inlet; providing the gas to an input leg of the toroidal chamber; and driving an alternating current through at least one coil winding around at least a segment of a donut-shaped ferrite encircling a portion of the remote plasma source chamber. The ferrite surrounds one of two legs of the remote plasma source chamber and a second donut ferrite and a second coil. The method further includes cleaning the RPS chamber without opening or depressurizing the RPS chamber.

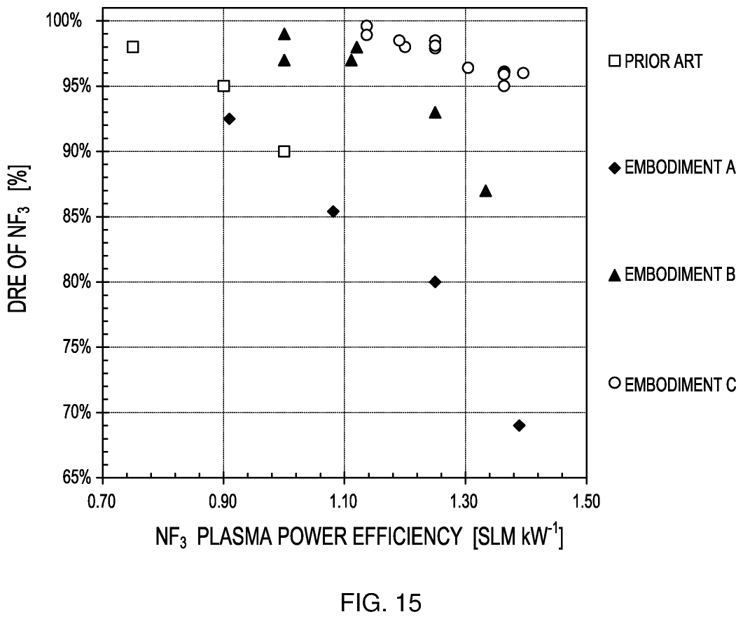

FIG. 15 illustrates measured data for the dissociation of NF₃ relative to power efficiency for different diffuser topologies. This data was obtained by running an RPS coupled to a plasma process chamber, and performing spectroscopy-based measurements on the RPS effluent chemistry. The x-axis is a composite variable of the gas flow rate (in units of SLM) divided by the power applied to the chamber/plasma (in units of kW). Thus, the x-axis represents a measure of the “efficiency” of the diffuser design, in terms of ability to sustain a plasma. For a given RPS gas diffuser embodiment plotted in FIG. 15, the extent to which the data extends to the right demonstrates the efficacy of that design in sustaining an NF₃ plasma at high gas flow rates and/or lower power levels.

DRE is also an important measure of performance because, as demonstrated in FIG. 15, one can achieve an “efficient” plasma (i.e., a high ratio of SLM:kW), but with a low DRE (likely because some gas escapes the chamber unmodified). Although measurements for NF₃ are shown, these relationships are expected to also be seen for other remote plasma feed gases known to those of skill in the art.

Thus, an ideal diffusor topology tends toward the upper right of the chart. As seen, the prior art (e.g., FIGS. 1-2) showed a DRE of between 90% and 97%, but low SLM:kW efficiency. Embodiment A, with topology similar to that in FIG. 9, demonstrates nearly identical performance to the prior art at lower SLM:kW ratios and also enables the ability for very high SLK:kW efficiency, albeit at the sacrifice of high DRE. Embodiment B, which topology is similar to that in FIG. 10, showed vast improvement over the topologies of FIGS. 1-3 and FIG. 9, but the maximum SLM:kW ratio is reduced slightly and the DRE at SLM:kW ratios greater than 1.2 is less than desirable. Embodiment C, with topology similar to that in FIG. 6, demonstrated the best performance, maintaining a DRE of NF₃ greater than 95% over the widest SLM:kW range. All the configurations (embodiments) shown in FIG. 15 have essentially identical RPS chamber volumes, power coupling methods, operating parameters, and test methods; thus, the wide variation in performance between embodiments illustrates the sensitivity and importance of toroidal chamber shape and inlet and outlet locations and the resulting gas diffusion and distribution within a remote plasma source.

The terms and expressions employed herein are used as terms and expressions of description and not of limitation, and there is no intention, in the use of such terms and expressions, of excluding any equivalents of the features shown and described or portions thereof. Each of the various elements disclosed herein may be achieved in a variety of manners. This disclosure should be understood to encompass each such variation, be it a variation of an embodiment of any apparatus embodiment, a method or process embodiment, or even merely a variation of any element of these. Particularly, it should be understood that the words for each element may be expressed by equivalent apparatus terms or method terms-even if only the function or result is the same. Such equivalent, broader, or even more generic terms should be considered to be encompassed in the description of each element or action. Such terms can be substituted where desired to make explicit the implicitly broad coverage to which this invention is entitled.

As but one example, it should be understood that all action may be expressed as a means for taking that action or as an element which causes that action. Similarly, each physical element disclosed should be understood to encompass a disclosure of the action which that physical element facilitates. Regarding this last aspect, by way of example only, the disclosure of a “protrusion” should be understood to encompass disclosure of the act of “protruding”-whether explicitly discussed or not—and, conversely, were there only disclosure of the act of “protruding,” such a disclosure should be understood to encompass disclosure of a “protrusion”. Such changes and alternative terms are to be understood to be explicitly included in the description.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

1. A remote plasma source comprising:
a toroidal chamber;
a first inlet;
an outlet;
a reference plane bisecting the toroidal chamber, and the outlet, wherein the first inlet is substantially perpendicular to the reference plane and thereby configured to direct a fluid into the toroidal chamber substantially perpendicularly to the reference plane; and
a magnetic field generating assembly encircling at least a portion of the toroidal chamber and configured to maintain a plasma within the toroidal chamber.

2. The remote plasma source of claim 1, wherein the toroidal chamber has an input leg, an output leg, and first and second interstitial legs spaced apart and connecting ends of the input and output legs.

3. The remote plasma source of claim 2, wherein the first inlet is arranged at a first end of the input leg.

4. The remote plasma source of claim 3, wherein a second inlet is arranged at the first end of the input leg and in an opposing direction to the first inlet.

5. The remote plasma source of claim 3, wherein a second inlet is arranged at a second end of the input leg and in an opposing direction to the first inlet.

6. The remote plasma source of claim 2, wherein the first inlet and a second inlet are configured to direct the fluid into the input leg in opposing directions.

7. The remote plasma source of claim 6, wherein the first and second inlets are arranged substantially along a common axis.

8. The remote plasma source of claim 2, wherein the input leg comprises a racetrack-shaped volume.

9. The remote plasma source of claim 8, wherein the input leg comprises perturbance fins configured to disrupt streamlined flow around a periphery of the input leg.

10. A remote plasma source comprising:
a toroidal chamber;
a magnetic field generating assembly configured to maintain a plasma within the toroidal chamber;
a showerhead type jet inlet arranged on a first outer side of the toroidal chamber and having a first fluid flow axis, configured to decelerate and diffuse fluid before the fluid enters the toroidal chamber, the showerhead type jet inlet comprising:
a first inlet portion with a first radius and a closed bottom;
a second inlet portion with a second radius greater than the first radius;
a plurality of showerhead type jets configured to redirect the fluid from the first fluid flow axis toward walls of the second inlet portion; and
the second inlet portion configured to direct the fluid into the toroidal chamber; and
an outlet arranged on a second outer side of the toroidal chamber, opposing the showerhead type jet inlet, and having a second fluid flow axis substantially parallel to the first fluid flow axis.

11. The remote plasma source of claim 10, wherein the toroidal chamber has an input leg, an output leg, and first and second interstitial legs spaced apart and connecting ends of the input and output legs.

12. The remote plasma source of claim 11, wherein the input leg and the output leg are both racetrack shaped.

13. The remote plasma source of claim 10, further comprising a magnetic field generating assembly encircling at least a portion of the toroidal chamber and configured to maintain a plasma within the toroidal chamber.

14. The remote plasma source of claim 10, wherein the first and second fluid flow axes are coextensive.

15. The remote plasma source of claim 10, wherein the first fluid flow axis is directed toward an interior wall directly opposite the showerhead type jet inlet.

16. A method for cleaning a process chamber using a remote plasma source effluent, the method comprising:
introducing gas to a toroidal chamber of a remote plasma source in a first direction, the toroidal chamber having an input leg, a first interstitial leg, a second interstitial leg, and an output leg, wherein the first direction is perpendicular to a reference plane bisecting the input leg, the first and second interstitial legs, and the output leg;
generating a magnetic field encircling at least a portion of the toroidal chamber;
maintaining a plasma within the toroidal chamber via the magnetic field configured to convert the gas to an activated gas;
providing the activated gas to the process chamber and reacting the activated gas with a deposit inside the process chamber to at least partially remove the deposit and form a reacted gas; and
exhausting the reacted gas from the process chamber.

17. The method of claim 16, wherein the gas has two equal path lengths through the toroidal chamber.

18. The method of claim 17, wherein the gas experiences substantially equal residence time along the two equal path lengths.

19. The method of claim 17, wherein the two equal path lengths correspond to substantially equal volumetric rates of gas transfer.

20. The method of claim 16, wherein the introducing gas is implemented via showerhead type jets that break up streamline flow of the gas entering the toroidal chamber.
